(19) United States
(12) Patent Application Publication
(10) Pub. No.: US 2018/0321548 A1
(43) Pub. Date: Nov. 8, 2018

(54) DISPLAY PANEL

(71) Applicant: Beijing Xiaomi Mobile Software Co., Ltd., Beijing (CN)

(72) Inventor: Guosheng LI, Beijing (CN)

(73) Assignee: Beijing Xiaomi Mobile Software Co., Ltd., Beijing (CN)

(21) Appl. No.: 15/972,807

(22) Filed: May 7, 2018

(30) Foreign Application Priority Data
May 8, 2017 (CN) 201710318432.0

(51) Int. Cl. G02F 1/1335; G02F 1/1368; G02F 1/1345

(52) U.S. Cl. CPC G02F 1/133514; G02F 1/1368; H01L 27/1214; G02F 2201/52; G02F 1/13452

(57) ABSTRACT

The present disclosure relates to a display panel. The display panel includes a plurality of display sets of pixels, each of the display sets including a white display subset corresponding to a white channel and a plurality of color display subsets corresponding to a plurality of primary color channels, wherein the white display subset has a first display area, and each of the color display subsets has a second display area, wherein the second display areas of the color display subsets are equal to one another, and the first display area of the white display subset is larger than each of the second display areas.

### CROSS-REFERENCE TO RELATED APPLICATIONS

This application is based on and claims priority to Chinese Patent Application 201710318432.0, filed on May 8, 2017, the entire contents of which are incorporated herein by reference.

### TECHNICAL FIELD

The present disclosure relates to the field of display technology, and more particularly to a display panel.

### BACKGROUND

A display panel is one of the most commonly used input and output electronic devices. A display panel has functions of displaying text information and image information. A liquid crystal display (LCD) panel is a type of commonly used display panel.

A LCD panel includes a plurality of display units of pixels, each display unit of the pixels may be divided into display subunits corresponding to red, green and blue color channels, respectively, and each display subunit may include a driving circuit, a liquid crystal layer, and color filters. The liquid crystal display panel may include a backlight for providing light for each of the display subunits, and a polarizing plate for changing the direction of the light.

Display subunit color filters are typically red, green and blue three-color filters, which have relatively poor light transmission capacity. When higher screen brightness is required, then the light intensity of the backlight has to be significantly increased, and more power has to be consumed.

### SUMMARY

This Summary is provided to introduce a selection of aspects of the present disclosure in a simplified form that are further described below in the Detailed Description. This Summary is not intended to identify key features or essential features of the claimed subject matter, nor is it intended to be used to limit the scope of the claimed subject matter.

Aspects of the disclosure provide a display panel including a plurality of display sets of pixels, each of the display sets including a white display subset corresponding to a white channel and a plurality of color display subsets corresponding to a plurality of primary color channels, wherein the white display subset has a first display area, and each of the color display subsets has a second display area, wherein the second display areas of the color display subsets are equal to one another, and the first display area of the white display subset is larger than each of the second display areas. In this way, the white display subset corresponding to the white channel having a large display area is added to each pixel. Since the color filter of the white display subset corresponding to the white channel has a strong light-transmitting ability, when the requirement for the brightness of the screen is the same, with the display panel provided in the present solution, a lower light intensity of the backlight can be used, and thereby the power consumed by the backlight can be saved

In an example, the plurality of primary color channels includes a red channel, a blue channel, and a green channel. In this way, different colors of pixels can be formed based on red, green, blue three primary color channels.

According to an aspect, each of the first and second display areas has a rectangular shape, and the first and second display areas have equal lengths and are arranged in parallel to one another.

According to another aspect, the first and second display areas in each of the display sets are arranged in a same order, and are parallel with one another with long-sides thereof being arranged vertically.

According to yet another aspect, the first and second display areas in each of the display sets are arranged in a same order, and are parallel with one another with long-sides thereof being arranged horizontally.

In an example, the first display area of the white display subset is less than half of a display area of the display set. In this way, it can be avoided that the white channel has too much impact on pixel color accuracy.

In another example, the first display area of the white display subset accounts for ⅓ of a display area of the display set.

According to an aspect, each of the white and color display subsets includes a thin film transistor (TFT).

According to another aspect, the display panel includes a gate circuit; and a data circuit, wherein a gate electrode of each of the TFTs is connected to the gate circuit, and wherein a source electrode of each of the TFTs is connected to the data circuit. In this way, turn-on or turn-off of the TFTs in the display subsets corresponding to the white channel and each of the primary color channels may be controlled by a common gate circuit.

According to yet another aspect, the display panel includes a first gate circuit; a second gate circuit; and a data circuit, wherein a source electrode of each of the TFTs is connected to the data circuit, wherein a gate electrode of each of the TFTs of the color display subsets is connected to the first gate circuit, and wherein a gate electrode of each of the TFTs of the white display subset is connected to the second gate circuit. In this way, the turn-on or turn-off of the TFTs in the display subsets corresponding to the white channel and each of the primary color channels may be controlled by the first gate circuit and the second gate circuit, respectively.

It is to be understood that both the foregoing general description and the following detailed description are illustrative and explanatory only and are not restrictive of the present disclosure.

### BRIEF DESCRIPTION OF THE DRAWINGS

The accompanying drawings, which are incorporated in and constitute a part of this specification, illustrate aspects consistent with the disclosure and, together with the description, serve to explain the principles of the disclosure.

FIG. 1 is a schematic structural diagram of a display panel according to an exemplary aspect of the present disclosure.

FIG. 2 is a schematic diagram of an arrangement of each color channel display area according to an exemplary aspect of the present disclosure.

FIG. 3 is a schematic diagram of an arrangement of each color channel display area according to an exemplary aspect of the present disclosure.

FIG. 4 is a schematic structural diagram of a display subunit according to an exemplary aspect of the present disclosure.

FIG. 5 is a schematic structural diagram of a display unit according to an exemplary aspect of the present disclosure.

FIG. 6 is a schematic structural diagram of a display unit according to an exemplary aspect of the present disclosure.

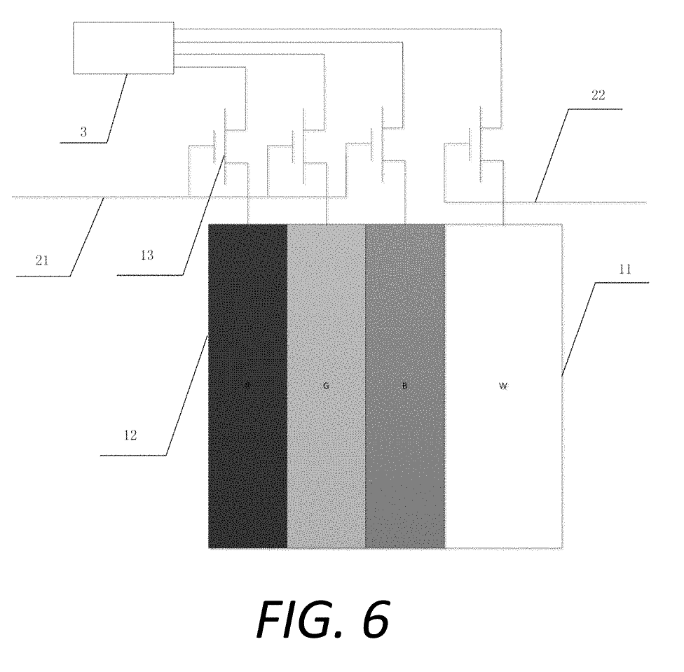

The specific aspects of the present disclosure, which have been illustrated by the accompanying drawings described above, will be described in detail below. These accompanying drawings and description are not intended to limit the scope of the present disclosure in any manner, but to explain the concept of the present disclosure to those skilled in the art via referencing specific aspects.

### DETAILED DESCRIPTION

Reference will now be made in detail to illustrative exemplary aspects, examples of which are illustrated in the accompanying drawings. The following description refers to the accompanying drawings in which the same numbers in different drawings represent the same or similar elements unless otherwise represented. The implementations set forth in the following description of illustrative aspects do not represent all implementations consistent with the disclosure. Instead, they are merely examples of apparatuses and methods consistent with aspects related to the disclosure as recited in the appended claims.

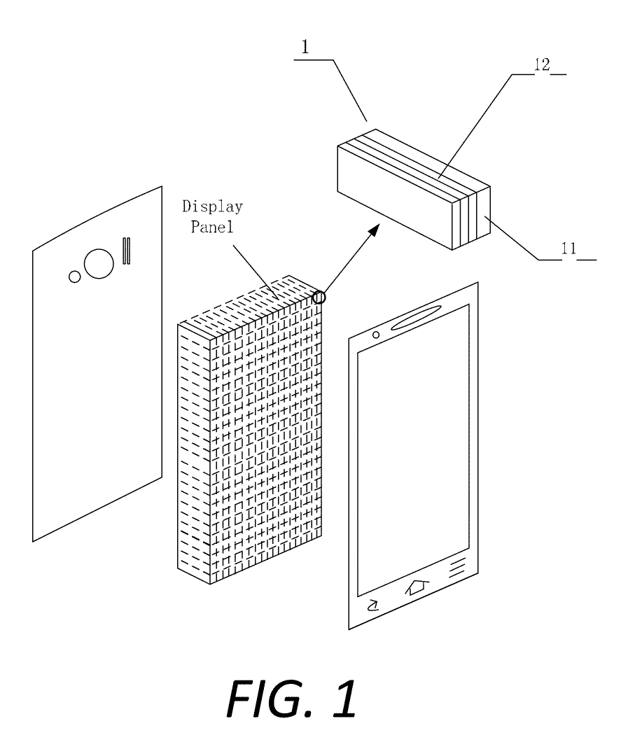

An aspect of the present disclosure provides a display panel, as shown in FIG. 1, the display panel includes a plurality of display units (e.g., display sets) 1 of a plurality of pixels, each display unit including a display subunit (e.g., white display subset) 11 corresponding to a white channel and a plurality of display subunits (e.g., color display subsets) 12 corresponding to primary color channels, wherein the display areas (e.g., second display areas) of the display subunits 12 corresponding to the plurality of primary color channels are equal to each other, and the display area (e.g., first display area) of the display subunit 11 corresponding to the white channel is larger than the display area of the display subunit 12 corresponding to each primary color channel.

In an aspect, the display panel may be a liquid crystal display panel, or an OLED display panel. When it is a liquid crystal display panel, the display unit 1 of each pixel may include a driving circuit, which may include a gate circuit and a data circuit, a liquid crystal layer and a color filter. When it is an OLED display panel, the display unit of each pixel may include a light emitting diode and color filters. In the present aspect, a liquid crystal display panel is described as an example, and the OLED display panel is similar with that, and thus the details thereof is omitted in the present aspect.

In the implementation, the display units 1 of a plurality of pixels is arranged in the display panel, each of the display units 1 is used for displaying the corresponding pixel on the screen when an image is displayed. For example, a display panel can display an image containing 1000*1000 pixels, which may indicate that the display panel contains 1000*1000 display units 1. Each pixel in the display panel may include one white channel and a plurality of primary color channels, that is, each pixel may include a white sub-pixel and a plurality of sub-pixels of primary colors. The display unit corresponding to each color channel can control the color of the corresponding sub-pixels. In this way, the plurality of sub-pixels are combined together, so that the pixel can display different colors.

Further, in each pixel, the display areas of the display subunits 12 corresponding to the plurality of primary color channels are equal to each other, and the display area of the display subunit 11 corresponding to the white channel is larger than the display area of each display subunit 12 corresponding to each of the primary color channels. As the light transmission rate of the white channel is much larger than those of the other primary color channels, with the same backlight power, the brightness of the screen can be effectively improved by using such a display panel comprising a white channel and a plurality of primary color channels. From other point of view, to reach a certain brightness of screen, by using the display panel disclosed in the present aspect, the brightness requirement of the backlight is relatively lower, so the power consumed by the backlight is lower. In addition, in the present aspect, since the display area of the display subunit 11 corresponding to the white channel (also referred to as the white display area) is larger than the display area of each display subunit 12 corresponding to each primary color channel (also referred to as the primary color display area), with the same backlight intensity, the display panel disclosed in this aspect can provide a higher screen brightness, and likewise, if the screen needs to reach a certain brightness, the backlight intensity can be relatively lower.

Optionally, the plurality of primary color channels includes a red channel, a blue channel, and a green channel.

In the implementation, each pixel may include three primary sub-pixels and one white sub-pixel, and the three primary sub-pixels correspond to three primary color channels. Particularly, the primary color channels may include a red channel, a green channel and a blue channel. In this way, color filters in the display subunit 12 corresponding to the primary color channels may be a red filter, a green filter, and a blue filter, respectively.

Optionally, the display areas of the display subunits 12 corresponding to the plurality of primary color channels and the display subunit 11 corresponding to the white channel are rectangular display areas arranged in a parallel way, and the length thereof is equal to each other.

In the implementation, the display areas of the display subunit 12 corresponding to the plurality of primary color channels and the display area of the display subunit 11 corresponding to the white channel may be rectangular display areas, and the lengths of the long sides of the rectangular display areas are equal to each other, and those display areas are arranged in a parallel way. It is not difficult to understand that since the areas of the display area of the display subunits 12 corresponding to the plurality of primary color channels are equal to each other, the area of the display area 11 of the display subunit corresponding to the white channel is larger than that of the display subunits 12, and the lengths of long sides of the display subunits are equal, then the width of the rectangular display area corresponding to the white channel is larger than the widths of the rectangular display areas corresponding to the primary color channels.

Alternatively, in the case where the display area of the display subunit is a rectangular display area, in the present aspect, two possible display area arrangement are provided:

Mode 1: the rectangular display areas of the respective display subunits in each display unit 1 are arranged in the same order and are parallel with each other with their long sides arranged in a vertical direction.

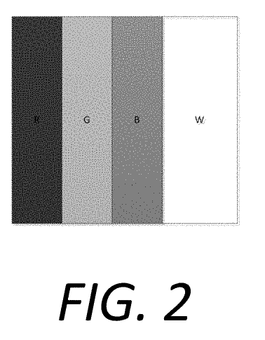

In the implementation, the rectangular display areas of the respective display subunits in each display unit 1 are arranged in the same order of color arrangement and are parallel with each other with their long sides arranged in the vertical direction, as shown in FIG. 2. In this aspect, as an example, the three primary colors may include red, green and blue colors, in each display unit 1, it is arranged in a form of one row and a plurality of columns in the order of red (corresponding to R area), green (corresponding to G area), blue (corresponding to B area), and white (corresponding to W area).

Mode 2: the rectangular display areas of the respective display subunits in each display unit 1 are arranged in the same order and are parallel with each other with their long sides being arranged in a horizontal direction.

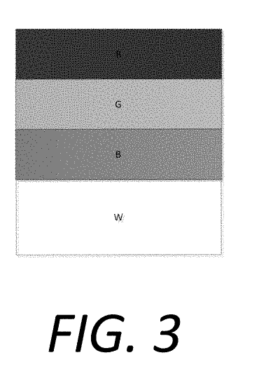

In the implementation, the rectangular display areas of the respective display subunits in each display unit 1 are arranged in the same order of color arrangement, and are parallel with each other, with their long-sides arranged in the horizontal direction, as shown in FIG. 3. In this aspect, as an example, the three primary colors include red, green and blue colors. And in each of the display units 1, it is arranged in a form of one column and a plurality of rows, in the order of red, green, blue, and white.

Optionally, the display area of the display subunit 11 corresponding to the white channel may be less than half of the display area of the display unit 1.

In the implementation, the white channel will affect the accuracy of color display, that is to say, the size of the white channel display area will not only affect the screen brightness under the same backlight intensity, but also the display color of the pixels on the screen. Due to the above fact, the larger the display area of the display subunit 11 corresponding to the white channel is, the brighter the screen will be, and the more inaccurate the display color of the pixel will be. Therefore, the display area of the display subunit 11 corresponding to the white channel in the display panel should not be too large, and should be less than half of the display area of the display unit 1 of each pixel (also referred to as the pixel display area), that is, ¼ pixel display area<white display area<½ pixel display area. In this way, the brightness of the screen under the same backlight intensity can be increased, and at the same time, each pixel display color will not deviate too much from the original color.

Optionally, the display area of the display subunit 11 corresponding to the white channel accounts for ⅓ of the display area of the display unit 1.

In the implementation, since the display area of the display subunit 11 corresponding to the white channel should be larger than the display area of the display subunit 12 corresponding to each of the primary color channels and smaller than half of the display area of the display unit 1 of each pixel, the display area of the display subunit 11 corresponding to the white channel may be selected to account for ⅓ of the display area of each display unit 1. In this way, the brightness of the screen under the same backlight intensity can be increased, and at the same time, each pixel display color may not deviate too much from the original color.

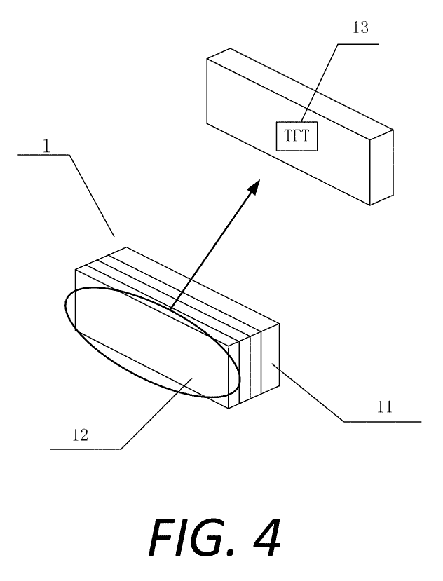

Optionally, each of the display subunits comprises a TFT 13, as shown in FIG. 4.

In the implementation, when the display panel is a liquid crystal display panel, each display subunit may include a transistor switch for driving liquid crystal molecules in the liquid crystal layer, which may be selected as a TFT (Thin Film Transistor). When a high voltage is applied to the gate electrode of the TFT 13, the TFT 13 is turned on between the source electrode and the drain electrode thereof. In this way, the data circuit may apply a voltage converted from the digital signal to the liquid crystal layer, so that the rotation of the liquid crystal molecules in the liquid crystal layer can be controlled to change the intensity of the light passing through the liquid crystal layer.

Optionally, there may be a plurality of circuit connection modes of the TFT 13 in each display subunit. Two possible connection modes are given as follows:

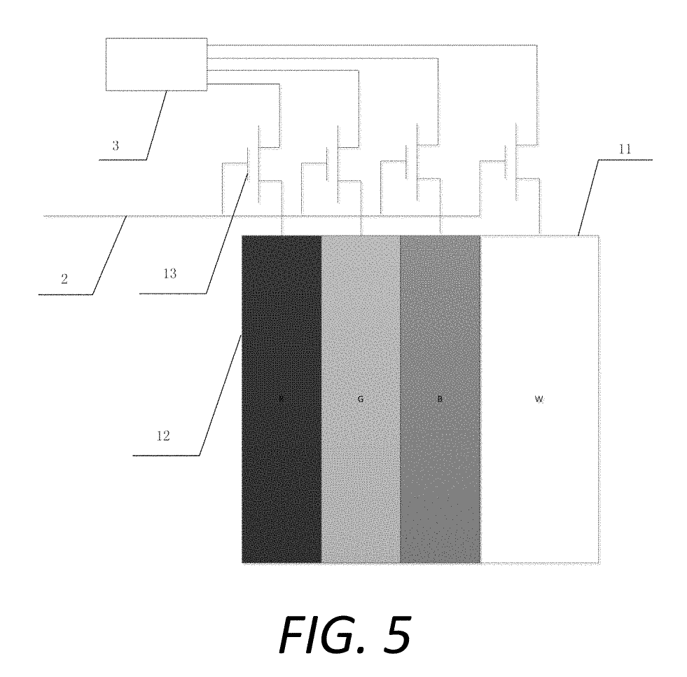

Mode 1, as shown in FIG. 5, the display panel includes a gate circuit 2 and a data circuit 3. The gate electrode of each TFT 13 is connected to the gate circuit 2, and the source electrode thereof is connected to the data circuit 3.

In the implementation, when the display panel is a liquid crystal display panel, the display panel may include a gate circuit and a data circuit, wherein the gate electrode of each TFT 13 of the display subunit may be connected to the gate circuit, and the source electrode is connected to the data circuit. In this way, the conduction of the TFT 13 of each display subunit can be controlled by a common gate circuit. When the gate circuit is turned on, a high voltage may be applied to the gate electrode of the TFT 13, and at this time, the source electrode and the drain electrode of the TFT 13 are turned on. Further, the data voltage (the data voltage is the voltage obtained by converting the image data by the data circuit) originally applied to the source electrode of the TFT 13 can be directly applied to the liquid crystal layer of each display subunit through the turned on source electrode and the drain electrode of the TFT 13, so that the rotation of the liquid crystal molecules in the liquid crystal layer can be controlled to change the intensity of the light passing through the liquid crystal layer.

It should be noted that the display panel provided in the present aspect can support the display mode one in which the display subunit 11 corresponding to the white channel operates alone, and also can support the display mode two in which only the display subunit 12 corresponding to the plurality of primary color channels is operated (i.e., the display subunit 11 corresponding to the white channel in this mode does not operate), and still can support the display mode three in which the display subunit 11 corresponding to the white channel and the display subunit 12 corresponding to the plurality of primary color channels both operate. After the gate circuit is turned on, the data circuit output of the display subunit 12 corresponding to the plurality of primary color channels can be controlled to be zero, that is, the display mode one is realized; or alternatively, the data circuit output of the display subunit 11 corresponding to the white channel can be controlled to be zero, that is, the display mode two is realized.

Mode 2, the display panel includes a first gate circuit 21, a second gate circuit 22, and a data circuit 3. The source electrode of each TFT switch is connected to the data circuit 3, and the gate electrode of the TFT switch of the display subunit 12 corresponding to each of the primary color channels is connected to the first gate circuit 21, and the gate electrode of the TFT switch of the display subunit 11 corresponding to each white channel is connected to the second gate circuit 22.

In the implementation, when the display panel is a liquid crystal display panel, the display panel may include a first gate 21, a second gate 22, and a data circuit 3, wherein the source electrode of each TFT switch is connected to the data circuit 3, the gate electrode of the TFT switch of the display subunit 12 corresponding to each of the primary color channels is connected to the first gate circuit 21, and the gate electrode of the TFT switch of the display subunit 11 corresponding to each white channel is connected to the second gate circuit 22. In this way, the TFT of the display subunit 11 corresponding to each of the primary color channels can be controlled by the first gate circuit 21, and the TFT of the display subunit 11 corresponding to the white channel can be controlled by the second gate circuit 22.

It should be noted that the display panel provided in the present aspect can support the display mode one in which the display subunit 11 corresponding to the white channel operates alone, and also can support the display mode two in which only the display subunits 12 corresponding to the plurality of primary color channels operate (i.e., the display subunit 11 corresponding to the white channel in this mode does not operate), and still can support the display mode three in which the display subunit 11 corresponding to the white channel and the display subunit 12 corresponding to the plurality of primary color channels cooperate. When the display mode one needs to be realized, only the second gate circuit 22 can be turned on, and only the TFT of the display subunit 11 corresponding to the white channel is turned on; when the display mode two needs to be realized, only the first gate circuit 21 can be turned on, then the TFT of the display subunit 12 corresponding to each of the primary color channels is turned on, and the TFT of the display subunit 11 corresponding to the white channel is not turned on; when the display mode three needs to be realized, the first gate 21 and the second gate 22 can be turned on together, and the TFTs of all the display subunits are turned on.

In the aspect of the present disclosure, the display panel may include a plurality of display units of a plurality of pixels, each display unit including a display subunit corresponding to a white channel and a plurality of display subunits corresponding to primary color channels, wherein the display areas of the display subunits corresponding to the plurality of primary color channels are equal, and the display area of the display subunit corresponding to the white channel is larger than the display area of each display subunit corresponding to each primary color channel. In this way, the display subunit corresponding to the white channel having a large display area is added to each pixel, and the color filter of the display subunit corresponding to the white channel has a strong light-transmitting ability. Therefore, when the screen brightness requirement is the same, with the display panel provided in the present solution, a lower light intensity of the backlight is needed, which can save the power consumed by the backlight.

It is noted that the various modules, sub-modules, units, and components in the present disclosure can be implemented using any suitable technology. For example, a module may be implemented using circuitry, such as an integrated circuit (IC). As another example, a module may be implemented as a processing circuit executing software instructions.

Other aspects of the present disclosure will be readily apparent to those skilled in the art upon consideration of the specification and practice of the disclosure disclosed herein. The present application is intended to cover any variations, uses, or adaptations of the present disclosure that follow the general principles of the present disclosure and include the common general knowledge or conventional technical means in the art without departing from the present disclosure. The specification and examples are to be regarded as illustrative only, and the true scope and spirit of the disclosure is indicated by the following claims.

It is to be understood that this disclosure is not limited to the precise constructions described above and shown in the accompanying drawings, and that various modifications and changes may be made without departing from the scope thereof. The scope of the present disclosure is limited only by the appended claims.

What is claimed is:

1. A display panel comprising:
a plurality of display sets of pixels, each of the display sets including a white display subset corresponding to a white channel and a plurality of color display subsets corresponding to a plurality of primary color channels,
wherein the white display subset has a first display area, and each of the color display subsets has a second display area,
wherein the second display areas of the color display subsets are equal to one another, and the first display area of the white display subset is larger than each of the second display areas.

2. The display panel according to claim 1, wherein the plurality of primary color channels includes a red channel, a blue channel, and a green channel.

3. The display panel according to claim 1, wherein each of the first and second display areas has a rectangular shape, and wherein the first and second display areas have equal lengths and are arranged in parallel to one another.

4. The display panel according to claim 3, wherein the first and second display areas in each of the display sets are arranged in a same order, and are parallel with one another with long-sides thereof being arranged vertically.

5. The display panel according to claim 3, wherein the first and second display areas in each of the display sets are arranged in a same order, and are parallel with one another with long-sides thereof being arranged horizontally.

6. The display panel according to claim 1, wherein the first display area of the white display subset is less than half of a display area of the display set.

7. The display panel according to claim 1, wherein the first display area of the white display subset accounts for ⅓ of a display area of the display set.

8. The display panel according to claim 1, wherein each of the white and color display subsets includes a thin film transistor (TFT).

9. The display panel according to claim 8, further comprising:
a gate circuit; and
a data circuit,
wherein a gate electrode of each of the TFTs is connected to the gate circuit, and
wherein a source electrode of each of the TFTs is connected to the data circuit.

10. The display panel according to claim 8, further comprising:
a first gate circuit;
a second gate circuit; and
a data circuit,
wherein a source electrode of each of the TFTs is connected to the data circuit,
wherein a gate electrode of each of the TFTs of the color display subsets is connected to the first gate circuit, and
wherein a gate electrode of each of the TFTs of the white display subset is connected to the second gate circuit.
